(19) United States
(12) Patent Application Publication
(10) Pub. No.: US 2024/0081499 A1
(43) Pub. Date: Mar. 14, 2024

(54) CASE, ELECTRONIC DEVICE COMPRISING THE SAME, AND METHOD OF MANUFACTURING THE CASE

(71) Applicant: SAMSUNG ELECTRONICS CO., LTD., Suwon-si (KR)

(72) Inventors: Jihwan CHUN, Suwon-si (KR); Hangyu HWANG, Suwon-si (KR); Jiwon PARK, Suwon-si (KR); Seungchang BAEK, Suwon-si (KR); Changhyeok SHIN, Suwon-si (KR); Sungho CHO, Suwon-si (KR); Minwoo YOO, Suwon-si (KR)

(21) Appl. No.: 18/518,367

(22) Filed: Nov. 22, 2023

Related U.S. Application Data
(63) Continuation of application No. PCT/KR2022/005411, filed on Apr. 14, 2022.

(30) Foreign Application Priority Data
May 26, 2021 (KR) 10-2021-0067390

(51) Int. Cl. A45C 11/00; H04B 1/3888

(52) U.S. Cl. CPC A45C 11/00; H04B 1/3888; A45C 2011/003

(57) ABSTRACT

A case includes a base plate, a hole formed through the base plate, a pattern that is on one surface of the base plate and includes a plurality of crests and a plurality of troughs. The case further includes an inclined area that is between the hole and the pattern, and at least one step that is between the inclined area and the hole, in which a first angle that the inclined area forms with a central axis of the hole is greater than a second angle that is an angle of view through the hole.

### CROSS-REFERENCE TO RELATED APPLICATIONS

This application is a national stage application of International Application No. PCT/KR2022/005411, designating the United States, filed on Apr. 14, 2022, in the Korean Intellectual Property Receiving Office and claiming priority to Korean Patent Application No. 10-2021-0067390, filed on May 26, 2021, in the Korean Intellectual Property Office, the disclosures of which are incorporated by reference herein in their entireties.

### TECHNICAL FIELD

The following description relates to a case, for example, to a case included in an electronic device.

### BACKGROUND ART

As to a pattern applied to the exterior of a portable electronic device, when a material is injected, a pattern shape is implemented in such a method as processing on a mold surface, and the pattern is implemented on a product through injection molding. To apply a pattern to a metal product, the pattern is implemented by cutting a material by using a tool operable according to computerized numerical control equipment. For example, computerized numerical control milling and shelf equipment may be used when shaping a pattern by using a metal material of a mobile device.

When shaping a pattern of a product intended to have a hole, the pattern is shaped first, and then, the hole is formed on the shaped pattern. A chemical processing is then performed to finish the product. For example, the chemical processing includes an anodizing film-shaping method or the like.

When a pattern is processed in a shape in a product, and hole processing is added, damage may occur primarily in a part where the pattern is formed, and a burr may be generated upon the hole processing. When the burr, which is generated around the hole after anodizing, is slightly detached, an anodizing film may be torn out, and a raw material may be exposed. Accordingly, a surface may be vulnerable to corrosion and the durability of the surface may decrease. In addition, when the anodizing film is torn out, a fine burr does not fall out and remains, and may thus glitter.

### DISCLOSURE OF THE INVENTION

### Technical Goals

Embodiments of the disclosure may decrease or prevent tearing due to a burr in equipment having a hole shape. Embodiments of the disclosure may improve the durability of a case or an electronic device by decreasing or preventing the tearing. Corrosion caused by the oxidation of an exposed raw material may be prevented.

### Technical Solutions

According to embodiments, a case includes a base plate; a hole formed through the base plate; a pattern that is on one surface of the base plate and includes a plurality of crests and a plurality of troughs; an inclined area that is between the hole and the pattern; and at least one step that is between the inclined area and the hole, in which a first angle that the inclined area forms with a central axis of the hole is greater than a second angle that is an angle of view through the hole.

According to embodiments, the plurality of crests and the plurality of troughs may be alternately arranged, and a radius of curvature of one of the plurality of crests may be different from a radius of curvature of one of the plurality of troughs.

According to embodiments, an electronic device includes a case, in which the case includes a base plate; a hole formed through the base plate; a pattern that is on one surface of the base plate and includes a plurality of crests and a plurality of troughs; an inclined area that is between the hole and the pattern; and at least one step that is between the inclined area and the hole, in which a first angle that the inclined area forms with a central axis of the hole is greater than a second angle that is an angle of view through the hole.

According to embodiments, a method of manufacturing a case includes forming a hole through a base plate; forming a pattern in an area spaced apart from the hole on one surface of the base plate; forming an inclined area between the hole and the pattern; and forming at least one step between the hole and the pattern, in which a first angle that the inclined area forms with a central axis of the hole is greater than a second angle that is an angle of view through the hole, and the pattern includes a plurality of crests and a plurality of troughs, in which the plurality of crests and the plurality of troughs are alternately arranged, and a radius of curvature of one of the plurality of crests is different from a radius of curvature of one of the plurality of troughs.

### Effects

According to embodiments, a case may decrease or prevent the tearing of an anodizing film in a method of forming a hole first, forming a pattern in a position spaced apart from the hole, and forming an incline and at least one step in an area between the hole and the pattern.

According to embodiments, the case may secure the sufficient angle of view of a camera by forming the at least one step, besides an inclined area.

According to embodiments, the case may decrease or prevent the interference of the angle of view by forming a relatively small angle of an inclined surface of the inclined area.

According to embodiments, the case may block, through the at least one step, some of the foreign materials entering the hole from the outside of the case.

According to embodiments, the case may reduce the generation of a burr when forming a pattern as the pattern is formed by applying a round-shape tool to an edge area.

According to embodiments, a radius of curvature and/or a distance may be variously set for a plurality of crests and a plurality of troughs that are included in the pattern, and a stereoscopic pattern, in which a pattern shape is different depending on an angle the pattern is viewed from, may be implemented.

In addition, various effects directly or indirectly ascertained through the present disclosure may be provided.

### BRIEF DESCRIPTION OF DRAWINGS

FIG. 1 is a block diagram illustrating an electronic device in a network environment according to an embodiment.

FIG. 2 is a flowchart schematically illustrating a method of manufacturing a case according to an embodiment.

FIG. 3A is a front view schematically illustrating a hole formed in a case according to an embodiment.

FIG. 3B is a front view schematically illustrating a hole and a pattern formed in the case according to an embodiment.

FIG. 3C is a front view schematically illustrating a hole, a pattern, and at least one step formed in the case according to an embodiment.

FIG. 4 is a cross-sectional view illustrating a case according to an embodiment.

FIG. 5 is another cross-sectional view illustrating a case according to an embodiment.

FIG. 6A is a plan view schematically illustrating one unit pattern formed on one pattern zone of a case according to an embodiment.

FIG. 6B is a plan view schematically illustrating a pattern filled in approximately half of one pattern zone after a plurality of unit patterns is formed on the pattern zone of the case according to an embodiment.

FIG. 6C is a plan view schematically illustrating a plurality of unit patterns filled in one pattern zone of the case according to an embodiment.

FIG. 7A is a side view schematically illustrating a pattern forming device for forming one unit pattern on a case according to an embodiment.

FIG. 7B is a magnified side view of a head of a pattern forming device according to an embodiment.

FIG. 8 is a cross-sectional view illustrating a unit pattern formed on a case according to an embodiment.

FIG. 9 is another cross-sectional view illustrating a unit pattern formed on a case according to an embodiment.

### BEST MODE FOR CARRYING OUT THE INVENTION

Hereinafter, embodiments will be described in detail with reference to the accompanying drawings. When describing the embodiments with reference to the accompanying drawings, like reference numerals refer to like elements and a repeated description related thereto will be omitted.

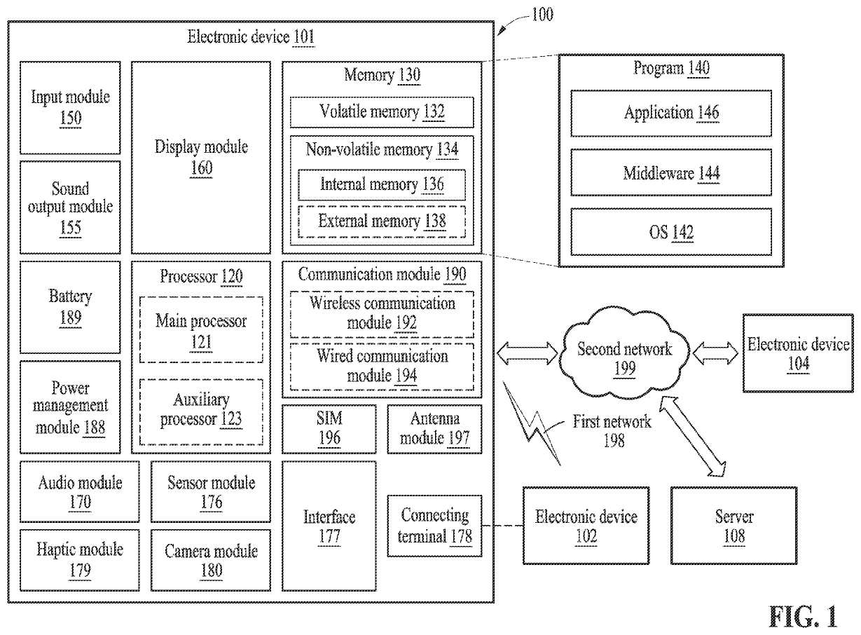

FIG. 1 is a block diagram illustrating an electronic device 101 in a network environment 100 according to various example embodiments. Referring to FIG. 1, the electronic device 101 in the network environment 100 may communicate with an electronic device 102 via a first network 198 (e.g., a short-range wireless communication network), or communicate with at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, a memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one (e.g., the connecting terminal 178) of the above components may be omitted from the electronic device 101, or one or more other components may be added in the electronic device 101. In some embodiments, some (e.g., the sensor module 176, the camera module 180, or the antenna module 197) of the components may be integrated as a single component (e.g., the display module 160).

The processor 120 may execute, for example, software (e.g., a program 140) to control at least one other component (e.g., a hardware or software component) of the electronic device 101 connected to the processor 120 and may perform various data processing or computation. According to an embodiment, as at least a part of data processing or computation, the processor 120 may store a command or data received from another component (e.g., the sensor module 176 or the communication module 190) in a volatile memory 132, process the command or the data stored in the volatile memory 132, and store resulting data in a non-volatile memory 134. According to an embodiment, the processor 120 may include a main processor 121 (e.g., a central processing unit (CPU) or an application processor (AP)) or an auxiliary processor 123 (e.g., a graphics processing unit (GPU), a neural processing unit (NPU), an image signal processor (ISP), a sensor hub processor, or a communication processor (CP)) that is operable independently from, or in conjunction with the main processor 121. For example, when the electronic device 101 includes the main processor 121 and the auxiliary processor 123, the auxiliary processor 123 may be adapted to consume less power than the main processor 121 or to be specific to a specified function. The auxiliary processor 123 may be implemented as separate from, or as part of the main processor 121.

The auxiliary processor 123 may control at least some of functions or states related to at least one (e.g., the display module 160, the sensor module 176, or the communication module 190) of the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an ISP or a CP) may be implemented as part of another component (e.g., the camera module 180 or the communication module 190) functionally related to the auxiliary processor 123. According to an embodiment, the auxiliary processor 123 (e.g., an NPU) may include a hardware structure specified for artificial intelligence model processing. An artificial intelligence model may be generated through machine learning. Such learning may be performed, for example, by the electronic device 101 in which an artificial intelligence model is executed, or via a separate server (e.g., the server 108). Learning algorithms may include, but are not limited to, for example, supervised learning, unsupervised learning, semi-supervised learning, or reinforcement learning. The artificial intelligence model may include a plurality of artificial neural network layers. An artificial neural network may include, for example, a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more thereof, but is not limited thereto. The artificial intelligence model may additionally or alternatively include a software structure other than the hardware structure.

The memory 130 may store various pieces of data used by at least one component (e.g., the processor 120 or the sensor module 176) of the electronic device 101. The various pieces of data may include, for example, software (e.g., the program 140) and input data or output data for a command related thereto. The memory 130 may include the volatile memory 132 or the non-volatile memory 134.

The program 140 may be stored as software in the memory 130 and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output a sound signal to the outside of the electronic device 101. The sound output module 155 may include, for example, a speaker or a receiver. The speaker may be used for general purposes, such as, for example, playing multimedia or playing record. The receiver may be used to receive an incoming call. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to sense a touch, or a pressure sensor adapted to measure the intensity of force incurred by the touch.

The audio module 170 may convert a sound into an electrical signal and vice versa. According to an embodiment, the audio module 170 may obtain the sound via the input module 150 or output the sound via the sound output module 155 or an external electronic device (e.g., the electronic device 102 such as, for example, a speaker or headphones) directly or wirelessly connected to the electronic device 101.

The sensor module 176 may detect an operational state (e.g., power or temperature) of the electronic device 101 or an environmental state (e.g., a state of a user) external to the electronic device 101 and generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., by wire) or wirelessly. According to an embodiment, the interface 177 may include, for example, a high-definition multimedia interface (HDMI), a universal serial bus (USB) interface, a secure digital (SD) card interface, or an audio interface.

The connecting terminal 178 may include a connector via which the electronic device 101 may be physically connected to the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or a movement) or an electrical stimulus which may be recognized by a user via his or her tactile sensation or kinesthetic sensation. According to an embodiment, the haptic module 179 may include, for example, a motor, a piezoelectric element, or an electric stimulator.

The camera module 180 may capture a still image and moving images. According to an embodiment, the camera module 180 may include one or more lenses, image sensors, ISPs, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more CPs that are operable independently of the processor 120 (e.g., an AP) and that support a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module, or a power line communication (PLC) module). A corresponding one of these communication modules may communicate with the external electronic device 104 via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., a LAN or a wide area network (WAN)). These various types of communication modules may be implemented as a single component (e.g., a single chip), or may be implemented as multiple components (e.g., multiple chips) separate from each other. The wireless communication module 192 may identify and authenticate the electronic device 101 in a communication network, such as the first network 198 or the second network 199, for example, using subscriber information (e.g., international mobile subscriber identity (IMSI)) stored in the SIM 196.

The wireless communication module 192 may support a 5G network after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., a mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), an array antenna, analog beamforming, or a large-scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., an external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in a communication network, such as, for example, the first network 198 or the second network 199, may be selected by, for example, the communication module 190 from the plurality of antennas. The signal or power may be transmitted or received between the communication module 190 and the external electronic device via the at least one selected antenna. According to an embodiment, another component (e.g., a radio frequency integrated circuit (RFIC)) other than the radiating element may be additionally formed as part of the antenna module 197.

According to an embodiment, the antenna module 197 may form a mmWave antenna module. According to an embodiment, the mmWave antenna module may include a PCB, an RFIC disposed on a first surface (e.g., the bottom surface) of the PCB or adjacent to the first surface and capable of supporting a designated high-frequency band (e.g., the mmWave band), and a plurality of antennas (e.g., array antennas) disposed on a second surface (e.g., the top or a side surface) of the PCB, or adjacent to the second surface and capable of transmitting or receiving signals in the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the external electronic devices 102 and 104 may be a device of the same type as or a different type from the electronic device 101. According to an embodiment, all or some of operations to be executed at the electronic device 101 may be executed at one or more of external electronic devices (e.g., the external electronic devices 102 and 104, or the server 108). For example, if the electronic device 101 needs to perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra-low-latency services using, e.g., distributed computing or MEC. In an embodiment, the external electronic device 104 may include an Internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., a smart home, a smart city, a smart car, or healthcare) based on 5G communication technology or IoT-related technology.

The electronic device according to the embodiments disclosed herein may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic device is not limited to those described above.

It should be appreciated that embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B or C”, “at least one of A, B and C”, and “at least one of A, B, or C”, may include any one of, or all possible combinations of the items enumerated together in a corresponding one of the phrases. As used herein, such terms as “1st” and “2nd,” or “first” and “second” may be used to simply distinguish a corresponding component from another and does not limit the components in other aspect (e.g., importance or order). It is to be understood that if a component (e.g., a first component) is referred to, with or without the term “operatively” or “communicatively”, as “coupled with”, “coupled to”, “connected with”, or “connected to” another component (e.g., a second component), it means that the component may be coupled with the other component directly (e.g., by wire), wirelessly, or via a third component.

As used in connection with embodiments of the disclosure, the term “module” may include a unit implemented in hardware, software, or firmware, and may interchangeably be used with other terms, for example, “logic”, “logic block”, “part”, or “circuitry”. A module may be a single integral component, or a minimum unit or part thereof, adapted to perform one or more functions. For example, according to an embodiment, the module may be implemented in a form of an application-specific integrated circuit (ASIC).

Embodiments as set forth herein may be implemented as software (e.g., the program 140) including one or more instructions that are stored in a storage medium (e.g., an internal memory 136 or an external memory 138) that is readable by a machine (e.g., the electronic device 101). For example, a processor (e.g., the processor 120) of the machine (e.g., the electronic device 101) may invoke at least one of the one or more instructions stored in the storage medium and execute it. This allows the machine to be operated to perform at least one function according to the at least one instruction invoked. The one or more instructions may include code generated by a compiler or code executable by an interpreter. The machine-readable storage medium may be provided in the form of a non-transitory storage medium. Here, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to embodiments of the disclosure may be included and provided in a computer program product. The computer program product may be traded as a product between a seller and a buyer. The computer program product may be distributed in the form of a machine-readable storage medium (e.g., compact disc read-only memory (CD-ROM)), or be distributed (e.g., downloaded or uploaded) online via an application store (e.g., PlayStore™), or between two user devices (e.g., smartphones) directly. If distributed online, at least part of the computer program product may be temporarily generated or at least temporarily stored in the machine-readable storage medium, such as, for example, a memory of the manufacturer's server, a server of the application store, or a relay server.

According to embodiments, each component (e.g., a module or a program) of the above-described components may include a single entity or multiple entities, and some of the multiple entities may be separately disposed in different components. According to embodiments, one or more of the above-described components or operations may be omitted, or one or more other components or operations may be added. Alternatively or additionally, a plurality of components (e.g., modules or programs) may be integrated into a single component. In such a case, according to embodiments, the integrated component may still perform one or more functions of each of the plurality of components in the same or similar manner as they are performed by a corresponding one of the plurality of components before the integration. According to embodiments, operations performed by the module, the program, or another component may be carried out sequentially, in parallel, repeatedly, or heuristically, or one or more of the operations may be executed in a different order or omitted, or one or more other operations may be added.

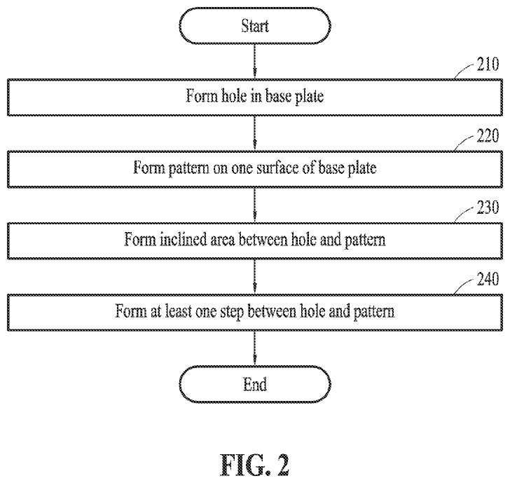

FIG. 2 is a flowchart schematically illustrating a method of manufacturing a case according to an embodiment.

Referring to FIG. 2, the method of manufacturing the case may include operation 210 of forming a hole in a base plate, operation 220 of forming a pattern on one surface of the base plate, operation 230 of forming an inclined area between the hole and the pattern, and operation 240 of forming at least one step between the hole and the pattern. In this case, the base plate may be a component forming the exterior of an electronic device (e.g., the electronic device 101 of FIG. 1).

The method of manufacturing the case may perform operation 210 of forming the hole prior to operation 220 of forming the pattern. In other words, the hole may be formed before the pattern in the base plate. Since the pattern is processed after the hole is formed on the base plate, the generation of a fine burr due to the interference of a rim line of the hole with the pattern may decrease or be prevented. For example, in operation 220 of forming the pattern, the pattern may be formed in an area spaced apart at a certain distance from the rim line of the hole. For example, a distance (d) from a line of the pattern adjacent to the hole to the rim line of the hole may be about 0.05 millimeters (mm). In at least one embodiment, the distance ranges from about 0.04 mm to 0.06 mm, and in some embodiments, the distance ranges from 0.045 mm to 0.55 mm. Accordingly, the distance defines a separation area that separates the line of the pattern from the rim line of the hole. Although the separation area is shown as having a circular shape, it should be appreciated that the separation area can have other various shapes without departing from the scope of the present disclosure.

Operation 220 of forming the pattern in the area spaced apart from the hole on the surface of the base plate, operation 230 of forming the inclined area between the hole and the pattern, and operation 240 of forming the at least one step between the hole and the pattern may be performed in whatever order. For example, operation 230 of forming the inclined area and operation 240 of forming the at least one step may be performed after operation 220 of forming the pattern.

For example, when operation 230 of forming the inclined area is performed before operation 240 of forming the at least one step, the amount of the base plate being cut while operation 230 is performed may relatively increase, and the amount of the base plate being cut while operation 240 is performed may relatively decrease. For example, when operation 230 of forming the inclined area is performed after operation 240 of forming the at least one step, the amount of the base plate being cut while operation 230 is performed may relatively decrease, and the amount of the base plate being cut while operation 240 is performed may relatively increase.

In operation 220 of forming the pattern on the surface, the pattern may be formed in the area spaced apart from the hole or may be formed adjacent to the hole.

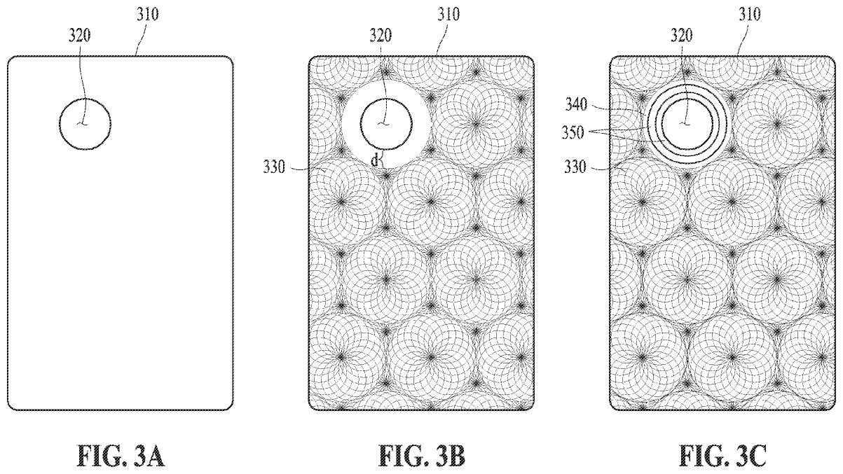

FIG. 3A is a front view schematically illustrating a hole formed in a case according to an embodiment, FIG. 3B is a front view schematically illustrating a hole and a pattern formed in the case according to an embodiment, and FIG. 3C is a front view schematically illustrating a hole, a pattern, and at least one step formed in the case according to an embodiment.

Referring to FIGS. 3A to 3C, the case may include a base plate 310, a hole 320 formed through one surface of the base plate 310, and a pattern 330 formed in an area spaced apart from the hole 320. In addition, the case may also include an inclined area 340 and at least one step 350, which are formed between the hole 320 and the pattern 330. Although the number of the at least one step 350 is illustrated as being two in the drawings, the numbers are not limited thereto.

When the case forms the hole 320 first (see FIG. 3A) and then forms the pattern 330 (see FIG. 3B), a burr may decrease or be prevented. In other words, when the hole 320 is processed in a place where the pattern 330 is formed, a burr may be generated, or the pattern 330 around the hole 320 may be transformed. On the other hand, when a hole is formed on a previously formed surface, a burr may be generated due to the interference of a pattern with the hole, or the shape of the pattern may be distorted. The case may have improved durability by forming the hole 320 first.

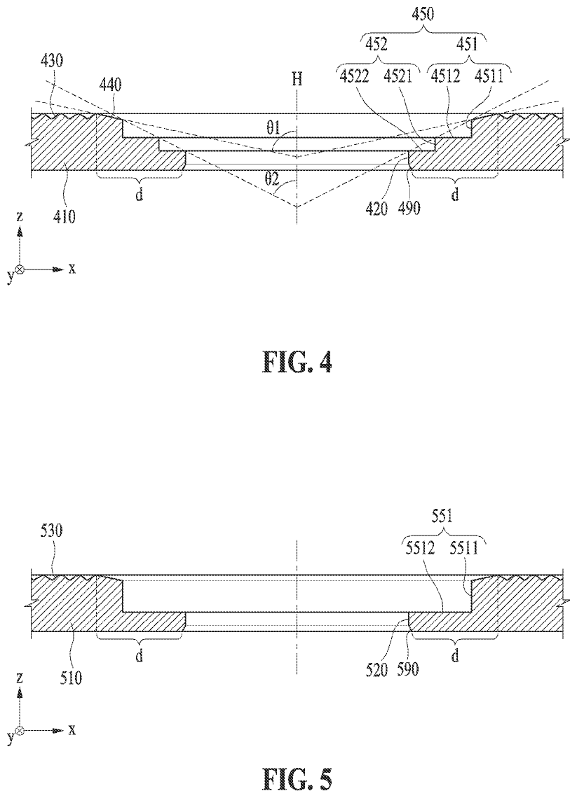

FIG. 4 is a cross-sectional view illustrating a case according to an embodiment.

Referring to FIG. 4, the case may include a base plate 410, a hole 420 formed through the base plate 410, a pattern 430 formed on one surface of the base plate 410, an inclined area 440 formed between the hole 420 and the pattern 430, at least one step 450 formed between the inclined area 440 and the hole 420, and an inclined area 490 formed in a part where the hole 420 is connected to a bottom surface of the base plate 410.

The base plate 410 may be a case forming the exterior of an electronic device (e.g., the electronic device 101 of FIG. 1). For example, the base plate 410 may provide a space for accommodating various components necessary to operate the electronic device (e.g., the electronic device 101 of FIG. 1). The base plate 410 may include an accommodation space for accommodating, for example, at least one of the processor 120, the memory 130, the input module 150 (e.g., a keyboard and/or a microphone), the sound output module 155, the audio module 170, the sensor module 176, the interface 177, the connecting terminal 178, the haptic module 179, the communication module 190, the SIM 196, and the antenna module 197 of FIG. 1.

The hole 420 may be formed through the base plate 410. The hole 420 may be formed through in a z-axis direction, for example. The hole 420 may be circular, for example. In the present disclosure, a central axis H of the hole 420 refers to a virtual line that passes through the center of the hole 420 and is parallel to a passing-through direction. For example, when a hole is polygonal, not circular, the central axis H may refer to a virtual line that passes through the center of the hole and is parallel to a direction passing through the hole.

The hole 420 may provide a path of light such that the light may enter, for example, the camera module 180 of FIG. 1. The hole 420 may be set to have a pertinent size such that, for example, the camera module 180 may secure a sufficient angle of view.

The pattern 430 may be formed on one surface of the base plate 410. For example, the pattern 430 may be formed on an upper surface of the base plate 410. In the present disclosure, the upper surface of the base plate 410 may be a surface exposed to the outside of the base plate 410. For example, the base plate 410 may include an accommodation space for accommodating components of the electronic device in a −z direction, which is an inward direction, and may be exposed to the outside in a +z direction, which is an outward direction. The pattern 430 may be formed on a surface facing the +z direction of the base plate 410.

The pattern 430 may be spaced apart from the hole 420 to define a separation area. For example, the pattern 430 may be spaced apart from a rim line of the hole 420 based on an x-y plane. According to this formation, the generation of a burr or the distortion of a surface shape due to the interference of the hole 420 with the pattern 430 may decrease or be prevented.

The inclined area 440 may be formed between the pattern 430 and the at least one step 450, e.g., in the separation area. In other words, the inclined area 440 may be spaced apart from the central axis H of the hole 420 farther than the at least one step 450. In addition, the inclined area 440 may include an inclined surface that is inclined downward in a direction from the pattern 430 to the hole 420. In other words, the inclined area 440 may include the inclined surface that is further inclined in the −z direction as being closer to the central axis H of the hole 420. A first angle θ1 formed by the inclined area 440 with the central axis H of the hole 420 may be greater than a second angle θ2, which is an angle of view through the hole 420. In this structure, the interference of the angle of view may be prevented. When the first angle θ1 is the same as or less than the second angle θ2, the inclined area 440 may interfere with the angle of view. When the pattern 430 is in the inclined area 440, diffusely reflected light may enter into the second angle θ2.

For example, since the incline of the inclined area 440 is more moderate than the angle of view through the hole 420, diffusely reflected light from the pattern 430 may be prevented from entering inside the base plate 410 through the hole 420. Specifically, a boundary between the pattern 430 and the inclined area 440 may include a pattern that causes diffused reflection. The first angle θ1 of the inclined area 440 may be greater than the second angle θ2 such that diffusely reflected light may not enter into the base plate 410.

The at least one step 450 may be spaced apart from the pattern 430. For example, the at least one step 450 may be between the hole 420 and the inclined area 440. The at least one step 450 may include a side surface that faces the central axis H and of which an edge contacts the inclined area 440 and a bottom surface having a normal line intersecting the side surface and parallel to the central axis H.

The at least one step 450 may filter out some of foreign materials from the outside. For example, a foreign material entering through the hole 420 from the outside may sit on the bottom surface. The amount of a foreign material seating in a first step 451, which is close to the exterior, is greater than the amount of a foreign material seating in the second step 452. Since the first step 451 is separated from the second step 452, a foreign material seats in the first step 451 that is less affected by the angle of view.

The at least one step 450 may include, for example, the first step 451 which is adjacent to the inclined area 440, and the second step 452 which is adjacent to the hole 420.

The first step 451 may include a first side surface 4511 contacting the inclined area 440 and a first bottom surface 4512 intersecting the first side surface 4511. An upper edge of the first side surface 4511 may be connected to a lower rim of the inclined area 440. An inner side edge of the first bottom surface 4512 may be connected to the second step 452.

The second step 452 may include a second side surface 4521 contacting the first bottom surface 4512 of the first step 451 and a second bottom surface 4522 intersecting the second side surface 4521.

The gradient of the inclined surface of the inclined area 440 may be less than a ratio of the height of the side surface to the width of the bottom surface. In other words, the first angle θ1, which is an angle formed by the inclined area 440 with the central axis H of the hole 420, may be greater than the second angle θ2, which is an angle formed with the central axis H of the hole 420 by a virtual line connecting an upper edge of the side surface to an inner side edge of the bottom surface. In this structure, the at least one step 450 may block the diffusely reflected light from the pattern 430.

The inclined area 490 may be formed between the hole 420 and the bottom surface of the base plate 410.

FIG. 5 is another cross-sectional view illustrating a case according to an embodiment.

Referring to FIG. 5, the case may include a base plate 510, a hole 520 formed through the base plate 510, a pattern 530 formed on one surface of the base plate 510, a step 551 formed between the hole 520 and the pattern 530, and an inclined area 590 formed in a part where the hole 520 is connected to a bottom surface of the base plate 510.

The step 551 may include a side surface 5511 facing the central axis of the hole 520 and a bottom surface 5512 having a normal line parallel to the central axis of the hole 520.

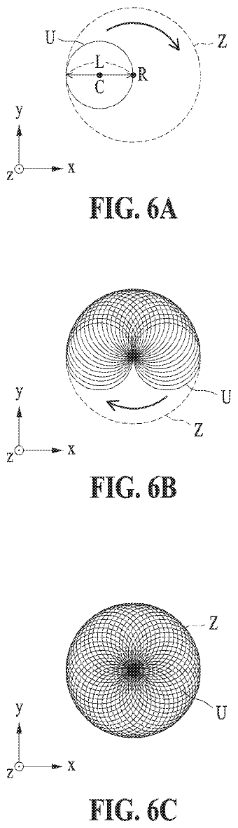

FIG. 6A is a plan view schematically illustrating one unit pattern formed on one pattern zone of a case according to an embodiment. FIG. 6B is a plan view schematically illustrating a pattern filled in approximately half of one pattern zone after a plurality of unit patterns is formed on the pattern zone of the case according to an embodiment. FIG. 6C is a plan view schematically illustrating a plurality of unit patterns filled in one pattern zone of the case according to an embodiment.

Referring to FIGS. 6A to 6C, a pattern zone Z may be formed by overlapping several unit patterns U. For example, one unit pattern U (see FIG. 6A) may be formed such that a rim of the unit pattern U may span a center R of the pattern zone Z. A diameter L of the unit pattern U may be the same as the radius of the pattern zone Z. After the unit pattern U is formed, the position of a center C may be shifted clockwise or counterclockwise (see FIG. 6B) based on the center R of the pattern zone Z, and a new unit pattern may be formed. By repeatedly performing this method, one complete pattern zone Z may be formed (see FIG. 6C). There may be a plurality of pattern zones Z on a base plate, and the plurality of pattern zones Z may overlap with one another.

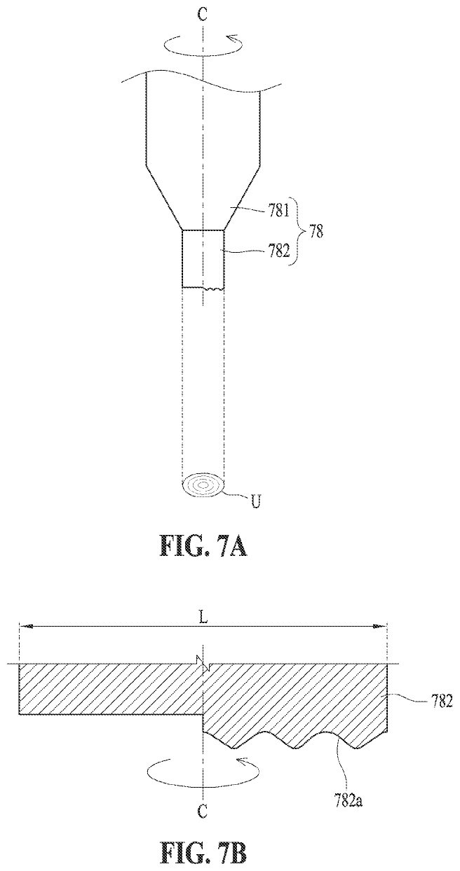

FIG. 7A is a side view schematically illustrating a pattern forming device for forming one unit pattern on a case according to an embodiment. FIG. 7B is a magnified side view of a head of a pattern forming device according to an embodiment.

Referring to FIGS. 7A and 7B, a pattern forming device 78 may include a device body 781 and a device head 782. The pattern forming device 78 may rotate around a central axis C and form a unit pattern U. The device head 782 may include a blade 782a for forming the unit pattern U on a base plate. An outer edge and an inner edge of the blade 782a may have a round shape, not a pointed shape. Such a shape of the blade 782a may decrease or prevent the generation of a burr on the base plate when forming a pattern.

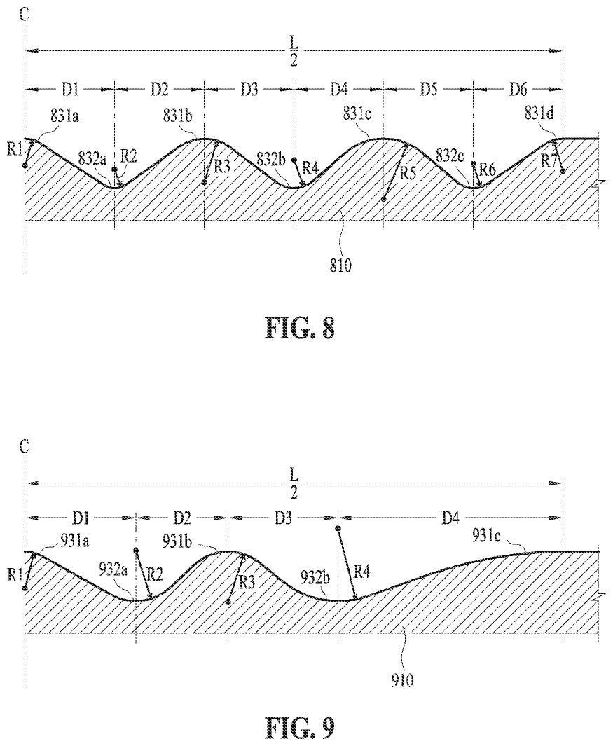

FIG. 8 is a cross-sectional view illustrating a unit pattern formed on a case according to an embodiment. FIG. 8 illustrates the cross-section of half of the unit pattern.

Referring to FIG. 8, a pattern formed on a base plate 810 may include a plurality of crests and a plurality of troughs. In the present disclosure, since the position of the center of the unit pattern may be determined based on the central axis C of the pattern forming device 78 (refer to FIG. 7A), the center of the unit pattern is denoted by C.

The plurality of crests may include a first crest 831a, a second crest 831b, a third crest 831c, and a fourth crest 831d in a direction away from the center C of the unit pattern. The plurality of troughs may include a first trough 832a, a second trough 832b, and a third trough 832c in the direction away from the center C of the unit pattern. The number of crests and troughs is not limited to the foregoing example.

The plurality of crests and the plurality of troughs may be alternately arranged. The plurality of crests and the plurality of troughs may each have a radius of curvature, and each radius of curvature may vary. For example, at least one of a first radius of curvature R1 of the first crest 831a, a second radius of curvature R2 of the first trough 832a, a third radius of curvature R3 of the second crest 831b, a fourth radius of curvature R4 of the second trough 832b, a fifth radius of curvature R5 of the third crest 831c, a sixth radius of curvature R6 of the third trough 832c, and/or a seventh radius of curvature R7 of the fourth crest 831d may be different. In other words, the plurality of crests and the plurality of troughs may each have an irregular radius of curvature.

At least one of a first distance D1 between the first crest 831a and the first trough 832a, a second distance D2 between the second crest 831b and the first trough 832a, a third distance D3 between the second crest 831b and the second trough 832b, a fourth distance D4 between the third crest 831c and the second trough 832b, a fifth distance D5 between the third crest 831c and the third trough 832c, and/or a sixth distance D6 between the fourth crest 831d and the third trough 832c may be different. In other words, the plurality of crests and the plurality of troughs may each have an irregular distance.

FIG. 9 is another cross-sectional view illustrating a unit pattern formed on a case according to an embodiment.

Referring to FIG. 9, a pattern formed on a base plate 910 may include a plurality of crests and a plurality of troughs.

The plurality of crests may include a first crest 931a, a second crest 931b, and a third crest 931c in a direction away from a center C of the unit pattern. The plurality of troughs may include a first trough 932a and a second trough 932b in the direction away from the center C of the unit pattern.

The plurality of crests and the plurality of troughs may be alternately arranged. The plurality of crests and the plurality of troughs may each have a radius of curvature, and each radius of curvature may vary. For example, at least one of a first radius of curvature R1 of the first crest 931a, a second radius of curvature R2 of the first trough 932a, a third radius of curvature R3 of the second crest 931b, and/or a fourth radius of curvature R4 of the second trough 932b may be different. In other words, the plurality of crests and the plurality of troughs may each have an irregular radius of curvature.

At least one of a first distance D1, a second distance D2, a third distance D3, and/or a fourth distance D4, which are distances between the plurality of crests and the plurality of troughs, may be different. In other words, the plurality of crests and the plurality of troughs may each have an irregular distance.

According to embodiments, a case includes a base plate 410; a hole 420 formed through the base plate; a pattern 430 that is on one surface of the base plate and includes a plurality of crests and a plurality of troughs; an inclined area that is between the hole and the pattern; and at least one step 450 that is between the inclined area and the hole, in which a first angle that the inclined area forms with a central axis of the hole is greater than a second angle that is an angle of view through the hole.

According to embodiments, the inclined area may be formed between the pattern and the at least one step.

According to embodiments, the at least one step may be spaced apart from the pattern.

According to embodiments, the at least one step may include a side surface that faces a central axis of the hole and of which an edge contacts the inclined area and a bottom surface having a normal line intersecting the side surface and parallel to the central axis of the hole.

According to embodiments, the inclined area may be inclined downward in a direction from the pattern to the hole.

According to embodiments, the gradient of an inclined surface of the inclined area may be less than a ratio of the height of the side surface to the width of the bottom surface.

According to embodiments, there is a plurality of steps, and the plurality of steps may include a first step that is adjacent to the pattern and a second step that is between the first step and the hole.

According to embodiments, the first step may include a first side surface, of which one edge contacts the inclined area, and a first bottom surface intersecting the first side surface, and the second step may include a second side surface, of which one edge contacts the first bottom surface, and a second bottom surface intersecting the second side surface.

According to embodiments, a radius of curvature of one of the plurality of crests may be different from a radius of curvature of another of the plurality of crests.

According to embodiments, a radius of curvature of one of the plurality of troughs may be different from a radius of curvature of another of the plurality of troughs.

According to embodiments, the plurality of crests may include a first crest and a second crest that are adjacent to one of the plurality of troughs and opposite to each other based on the trough, and respective distances spaced apart from the trough to the first crest and the second crest are different from each other.

According to embodiments, the plurality of troughs may include a first trough and a second trough that are adjacent to one of the plurality of crests and opposite to each other based on the crest, and respective distances spaced apart from the trough to the first crest and the second crest are different from each other.

According to embodiments, an electronic device includes a case, in which the case includes a base plate 410; a hole 420 formed through the base plate; a pattern 430 that is on one surface of the base plate and includes a plurality of crests and a plurality of troughs; an inclined area 440 that is between the hole and the pattern; and at least one step 450 that is between the inclined area and the hole, in which a first angle that the inclined area forms with a central axis of the hole is greater than a second angle that is an angle of view through the hole.

According to embodiments, a method of manufacturing a case includes forming a hole through a base plate; forming a pattern in an area spaced apart from the hole on one surface of the base plate; forming an inclined area between the hole and the pattern; and forming at least one step between the hole and the pattern, in which a first angle that the inclined area forms with a central axis of the hole is greater than a second angle that is an angle of view through the hole, and the pattern includes a plurality of crests and a plurality of troughs, in which the plurality of crests and the plurality of troughs are alternately arranged, and a radius of curvature of one of the plurality of crests is different from a radius of curvature of one of the plurality of troughs.

1. A case comprising:
a base plate;
a hole formed through the base plate;
a pattern that is on one surface of the base plate and comprises a plurality of crests and a plurality of troughs;
an inclined area that is between the hole and the pattern; and
at least one step that is between the inclined area and the hole, wherein
a first angle that the inclined area forms with a central axis of the hole is greater than a second angle that is an angle of view through the hole.

2. The case of claim 1, wherein the plurality of crests and the plurality of troughs are alternately arranged, and a radius of curvature of one of the plurality of crests is different from a radius of curvature of one of the plurality of troughs.

3. The case of claim 1, wherein the inclined area is between the pattern and the at least one step.

4. The case of claim 1, wherein the at least one step is spaced apart from the pattern.

5. The case of claim 1, wherein the at least one step comprises a side surface that faces a central axis of the hole and of which an edge contacts the inclined area and a bottom surface having a normal line intersecting the side surface and parallel to the central axis of the hole.

6. The case of claim 5, wherein a gradient of an inclined surface of the inclined area is less than a ratio of a height of the side surface to a width of the bottom surface.

7. The case of claim 1, wherein there is a plurality of steps, and the plurality of steps comprises a first step that is adjacent to the pattern and a second step that is between the first step and the hole.

8. The case of claim 7, wherein
the first step comprises a first side surface of which an edge contacts the inclined area and a first bottom surface intersecting the first side surface, and
the second step comprises a second side surface, of which an edge contacts the first bottom surface, and a second bottom surface intersecting the second side surface.

9. The case of claim 1, wherein a radius of curvature of one of the plurality of crests is different from a radius of curvature of another of the plurality of crests.

10. The case of claim 1, wherein a radius of curvature of one of the plurality of troughs is different from a radius of curvature of another of the plurality of troughs.

11. The case of claim 1, wherein
the plurality of crests is adjacent to one of the plurality of troughs and comprises a first crest and a second crest that are opposite to each other based on the one of the plurality of troughs, wherein
respective distances spaced apart from the one of the plurality of troughs to the first crest and the second crest are different from each other.

12. The case of claim 1, wherein
the plurality of troughs is adjacent to one of the plurality of crests and comprises a first trough and a second trough that are opposite to each other based on the one of the plurality of crests, wherein
respective distances spaced apart from the one of the plurality of crests to the first trough and the second trough are different from each other.

13. An electronic device comprising a case, wherein the case comprises:
a base plate;
a hole formed through the base plate;
a pattern that is on one surface of the base plate and comprises a plurality of crests and a plurality of troughs;
an inclined area that is between the hole and the pattern; and
at least one step that is between the inclined area and the hole, wherein
a first angle that the inclined area forms with a central axis of the hole is greater than a second angle that is an angle of view through the hole.

14. A method of manufacturing a case, the method comprising:
forming a hole through a base plate;
forming a pattern in an area spaced apart from the hole on one surface of the base plate;
forming an inclined area between the hole and the pattern; and
forming at least one step between the hole and the pattern,
wherein a first angle that the inclined area forms with a central axis of the hole is greater than a second angle that is an angle of view through the hole, and the pattern comprises a plurality of crests and a plurality of troughs, and
wherein the plurality of crests and the plurality of troughs are alternately arranged, and a radius of curvature of one of the plurality of crests is different from a radius of curvature of one of the plurality of troughs.

15. The method of claim 14, wherein the hole is formed prior to the pattern.

16. The method of claim 14, wherein the inclined area is between the pattern and the at least one step.

17. The method of claim 14, wherein the at least one step is spaced apart from the pattern.

18. The method of claim 14, wherein the forming the at least one step comprises:
forming a side surface that faces the central axis of the hole and of which an edge contacts the inclined area; and
forming a bottom surface having a normal line intersecting the side surface and parallel to the central axis of the hole.

19. The method of claim 14, wherein a radius of curvature of one of the plurality of crests is different from a radius of curvature of another of the plurality of crests.

20. The method of claim 14, wherein
the plurality of crests is adjacent to one of the plurality of troughs and comprises a first crest and a second crest that are opposite to each other based on the one of the plurality of troughs, wherein
respective distances spaced apart from the one of the plurality of troughs to the first crest and the second crest are different from each other.
